(19) United States
(12) Patent Application Publication
(10) Pub. No.: US 2013/0099255 A1
(43) Pub. Date: Apr. 25, 2013

(54) SEMICONDUCTOR LIGHT EMITTING DEVICE INCLUDING ZINC OXIDE-BASED TRANSPARENT CONDUCTIVE THIN FILM, AND FABRICATION METHOD THEREOF

(71) Applicant: SAMSUNG ELECTRONICS CO., LTD., Suwon-si (KR)

(72) Inventors: Jong Hyun LEE, Seoul (KR); Jung Hyun LEE, Ansan (KR); Ki Sung KIM, Suwon (KR); Suk Ho YOON, Seoul (KR); Young Sun KIM, Suwon (KR)

(73) Assignee: SAMSUNG ELECTRONICS CO., LTD., Suwon-si (KR)

(21) Appl. No.: 13/660,947

(22) Filed: Oct. 25, 2012

(30) Foreign Application Priority Data
Oct. 25, 2011 (KR) 10-2011-0109267

(51) Int. Cl. H01L 33/00

(52) U.S. Cl. 257/79; 438/22; 257/E33.001

(57) ABSTRACT

There is provided a semiconductor light emitting device having a zinc oxide-based transparent conductive thin film in which a Group III element is doped to have waveforms having a plurality of periods in a thickness direction.

### CROSS-REFERENCE TO RELATED APPLICATIONS

This application claims priority to Korean Patent Application No. 10-2011-0109267, filed on Oct. 25, 2011, in the Korean Intellectual Property Office, the disclosure of which is incorporated herein by reference.

### TECHNICAL FIELD APPLICATION

The present application relates to a semiconductor light emitting device including zinc oxide-based transparent conductive thin film, and a fabrication method thereof.

### BACKGROUND APPLICATION

A transparent conductive thin film is used in flat panel displays such as a thin film transistor-liquid crystal display (TFT-LCD), a plasma display panel (PDP), a field emission display (FED), an organic light emitting diode (OLED), and the like, a light emitting diode (LED), a solar cell, and the like, which use a photoelectric effect, and in this case, the transparent conductive thin film is required to have excellent light transmittance and conductivity in the visible light region of the electromagnetic spectrum as well as a near infrared region thereof.

Currently, Sn-doped In₂O₃ (In₂O₃:Sn), Indium Tin Oxide (ITO), is one of the materials most commonly used to form a high quality transparent conductive thin film. However, indium (In), a primary constituent element thereof, global reserves of which are extremely limited in comparison to those of tin (Sn) and zinc (Zn), is priced as highly as silver (Ag).

Thus, materials obtained by doping zinc oxide (ZnO) with a Group III cationic metal element such as aluminum (Al), gallium (Ga), indium (In), boron (B), or the like, have been intensively researched as a substitute material for ITO, and among them, a material obtained by doping Al in ZnO (ZnO:Al) and a material obtained by doping Ga in ZnO (ZnO:Ga) have come to prominence.

Zinc (Zn) as a primary constituent element of ZnO, reserves of which are about 1000 times or more than those of indium (In), is low in price and advantageously stable in a hydrogen plasma atmosphere (SiH₄), and so there have been moves to positively utilize Zn.

Recently, in order to form such a Group III element-doped ZnO thin film, a method of forming a thin film using sputtering has been attempted, which, however, involves a risk of damage to a surface of an element due to sputtering and there may be a difficulty in adjusting a concentration of the Group III element.

Also, a method of forming a Group III element-doped ZnO thin film using metal-organic chemical vapor deposition (MOCVD) has been attempted, but this method has a problem in which the Group III element is concentrated in the vicinity of the surface of the thin film, thereby degrading overall electrical characteristics of the thin film.

However, there is still room for improvement, for example, in terms of enhanced electrical characteristics and improved mass-production techniques of zinc oxide-based transparent conductive thin films.

### SUMMARY APPLICATION

A zinc oxide-based transparent conductive thin film having enhanced electrical characteristics and a fabrication method thereof are described herein.

Also, a method of fabricating a zinc oxide-based transparent conductive thin film which has excellent electrical characteristics and able to be mass-produced by using a batch-type metal-organic chemical vapor deposition (MOCVD) device, advantageous in terms of mass-production, is described.

According to an aspect of the present application, there is provided a semiconductor light emitting device having a zinc oxide-based transparent conductive thin film in which a Group III element is doped to have waveforms having a plurality of periods in a thickness direction.

According to another aspect of the present application, there is provided a method of fabricating a semiconductor light emitting device, including: forming a light emitting structure in which a first conductivity-type semiconductor layer, an active layer, and a second conductivity-type semiconductor layer are sequentially stacked on a substrate; performing a heat treatment on the substrate; injecting a zinc precursor and an oxidizing agent into a reaction chamber to grow a zinc oxide-based thin film; periodically injecting a Group III element precursor into the reaction chamber to dope the Group III element in the zinc oxide-based thin film, while the zinc oxide-based thin film is being grown; and performing a heat treatment on the resultant material.

The heat treatment, before growing the zinc oxide-based thin film, may be performed at a temperature ranging from 200° C. to 600° C. for 10 to 60 minutes.

The zinc precursor may include any one of DEZn and DMZn.

The precursor used as the Group III element may include at least one of TEGa and TMGa.

The growing of the zinc oxide-based thin film may be performed at a temperature ranging from 400° C. to 530° C. under an atmospheric pressure ranging from 2 to 30 torr.

The heat treatment may be performed on the resultant material at a temperature ranging from 200° C. to 600° C. for 40 to 120 minutes.

The zinc oxide-based transparent conductive thin film may be formed in a batch-type metal-organic chemical vapor deposition (MOCVD) device.

According to another aspect of the present application, there is provided a method of fabricating a semiconductor light emitting device, including: forming a light emitting structure in which a first conductivity-type semiconductor layer, an active layer, and a second conductivity-type semiconductor layer are sequentially stacked on a substrate; and repeatedly performing a process of injecting a zinc precursor, an oxidizing agent, and a precursor of a Group III element into a reaction chamber to grow a zinc oxide-based thin film from at least one surface of the light emitting structure, and then, injecting the zinc precursor and the oxidizing agent, excluding the Group III element precursor, into the reaction chamber to grow the zinc oxide-based transparent conductive thin film for 2 to 20 minutes.

The zinc precursor may include any one of DEZn and DMZn.

The precursor used as the Group III element may include at least one of TEGa and TMGa.

The growing of the zinc oxide-based thin film may be performed at a temperature ranging from 400° C. to 530° C. under an atmospheric pressure ranging from 2 to 30 torr.

The zinc oxide-based transparent conductive thin film may be formed in a batch-type metal-organic chemical vapor deposition (MOCVD) device.

Additional advantages and novel features will be set forth in part in the description which follows, and in part will become apparent to those skilled in the art upon examination of the following and the accompanying drawings or may be learned by production or operation of the examples. The advantages of the present teachings may be realized and attained by practice or use of various aspects of the methodologies, instrumentalities and combinations set forth in the detailed examples discussed below.

### BRIEF DESCRIPTION OF THE DRAWINGS

The drawing figures depict one or more implementations in accord with the present teachings, by way of example only, not by way of limitation. In the figures, like reference numerals refer to the same or similar elements.

FIG. 1 is a cross-sectional view illustrating a metal-organic chemical vapor deposition (MOCVD) device for fabricating a zinc oxide-based transparent conductive thin film according to an example of the present application;

FIG. 2 is a flow chart illustrating a process of a method of fabricating a zinc oxide-based transparent conductive thin film according to an example of the present application;

FIG. 3 is an SIMS graph of a concentration of a Group III element over a thickness of a zinc oxide-based transparent conductive thin film formed by using the method of fabricating a zinc oxide-based transparent conductive thin film according to an example of the present application; and

FIG. 4 is a schematic perspective view schematically showing a semiconductor light emitting device including a zinc oxide-based transparent conductive thin film according to an example of the present application.

### DETAILED DESCRIPTION

In the following detailed description, numerous specific details are set forth by way of examples in order to provide a thorough understanding of the relevant teachings. However, it should be apparent to those skilled in the art that the present teachings may be practiced without such details. In other instances, well known methods, procedures, components, and/or circuitry have been described at a relatively high-level, without detail, in order to avoid unnecessarily obscuring aspects of the present teachings.

A zinc oxide-based transparent conductive thin film, a fabrication method thereof, a semiconductor light emitting device including a zinc oxide-based transparent conductive thin film and a fabrication method thereof according to examples of the present application will hereinafter be described with reference to the accompanying drawings. The application may, however, be embodied in many different forms and should not be construed as being limited to the examples set forth herein. Rather, these examples are provided so that this disclosure will be thorough and complete, and will fully convey the scope of the application to those skilled in the art.

In the drawings, the shapes and dimensions of elements may be exaggerated for clarity, and the same reference numerals will be used throughout to designate the same or like components.

A measure of excellence of a transparent conductive thin film is dependent upon the density of appropriate free charges and a magnitude of free charge carrier mobility.

A method of increasing free charge density in the zinc oxide-based transparent conductive thin film includes a method of doping a Group III cationic metal element in a zinc oxide-based transparent conductive thin film to generate free charges and controlling the density of free charges by adjusting a doping concentration. In detail, when a Group III cationic metal element such as Al, Ga, or the like, is doped in a zinc oxide-based transparent conductive thin film, the Group III cationic metal element substitutes Zn, a bivalent element, free charges are generated due to a difference in quantity of electric charges, and the density of free charges is adjusted by a doping concentration.

When the doped Group III cationic metal element is evenly distributed in the entire zinc oxide-based transparent conductive thin film, the thin film can have excellent electrical characteristics.

The zinc oxide-based transparent conductive thin film according to an example of the present application is formed by using a metal-organic chemical vapor deposition (MOCVD) device.

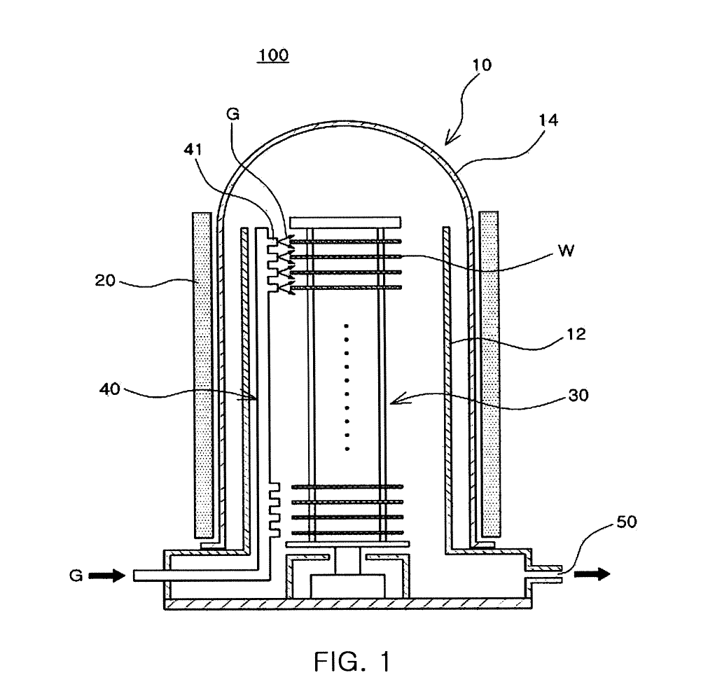

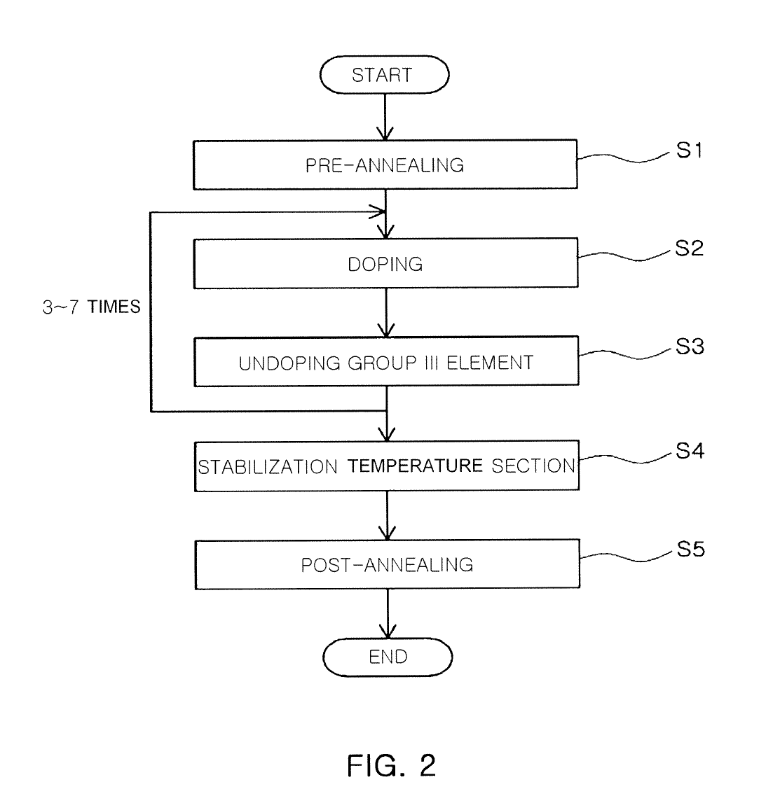

FIG. 1 is a cross-sectional view illustrating a MOCVD device for fabricating a zinc oxide-based transparent conductive thin film according to an example of the present application, and FIG. 2 is a flow chart illustrating a process of a method of fabricating a zinc oxide-based transparent conductive thin film according to an example of the present application;

As shown in FIG. 1, the MOCVD device may be a batch-type MOCVD device 100 and include a reaction chamber 10, a boat 30, and a gas supply unit 40.

The reaction chamber 10 has a dual-pipe structure including an internal chamber 12 and an external chamber 14 covering the internal chamber 12 to maintain air-tightness, and the interior of the reaction chamber 10 is heated by a heating unit 20 provided around the circumference of the reaction chamber 10.

A plurality of wafers (W) are loaded in the boat 30 having predetermined intervals therebetween, and the boat 30, in which the wafers (W) are loaded, may be disposed within the reaction chamber 10 or may be discharged to the outside. Thus, mass-production can be undertaken by loading tens of sheets of wafers (W) having predetermined intervals therebetween into the boat 30.

At least one gas supply unit 40 is disposed between the internal chamber 12 and the boat 30 and vertically extends in a height direction along the plurality of wafers (W) loaded in the height direction to supply a reactive gas (G) to the interior of the reaction chamber 10 through an injection nozzle 41.

A plurality of gas supply units 40 may be disposed to be spaced apart from one another around the circumference of the boat 30 such that a thin film can be uniformly grown on the entirety of the plurality of wafers (W) loaded in the height direction. In particular, each of the gas supply units 40 is individually connected to a flow meter (not shown) which controls and independently adjusts a supplied amount of the reactive gas (G). The reactive gas (G) within the reaction chamber 10 is discharged through an exhaust 50 after reaction.

In an example of the present application, the zinc oxide-based transparent conductive thin film is formed by using the MOCVD device.

With reference to FIG. 2, first, a wafer for forming a thin film is disposed within the reaction chamber 10 of the batch-type MOCVD device and the interior of the reaction chamber 10 is heated through the heating unit 20 to pre-anneal the wafer (W) (S1). Here, the pre-annealing is performed at a temperature ranging from 200° C. to 600° C. for 10 to 60 minutes.

Next, a Zn precursor, an oxidizing agent, and a precursor of a Group III element are injected, along with a carrier gas such as nitrogen (N₂) or argon (Ar), into the reaction chamber 10 through the injection nozzle 41 of the gas supply unit 40 in order to grow a zinc oxide-based thin film on the wafer (W). This section of the process is known as a doping operation (S2). Here, diethylzinc (DEZn), dimethylzinc (DMZn), or the like, may be used as the zinc precursor, and triethylgallium (TEGa), trimethylgallium (TMGa), or the like, may be used as the Group III element precursor. A process pressure is 2 to 300 torr and the process may be performed at a temperature ranging from 400° C. to 530° C. for 10 to 20 minutes.

Then, the zinc (Zn) precursor and the oxidizing agent are continuously injected, along with the carrier gas such as Nitrogen (N₂) or argon (Ar), through the injection nozzle 41 of the gas supply unit 40 within the reaction chamber 10, and supply of the Group III element precursor to the reaction chamber 10 is limited for 2 to 20 minutes. Namely, only the zinc (Zn) precursor and the oxidizing agent, excluding the Group III element precursor, are injected into the reaction chamber to grow the zinc oxide-based thin film. This section of the process is known as an undoping operation (S3).

The doping operation (S2) and the undoping operation (S3) are repeatedly performed three to seven times until such time as the zinc oxide-based transparent conductive thin film is formed to have a desired thickness.

Thereafter, in order to raise the temperature within the reaction chamber 10 for a certain time, the interior of the reaction chamber 10 is heated by the using the heating unit 20 for 10 to 120 minutes (S4) in a stabilization temperature section (S4).

Then, in order to improve free charge mobility and the density characteristics of free charges of the thin film, post-annealing is performed at a temperature ranging from 200° C. to 600° C. for 40 to 120 minutes (S5).

When the zinc oxide-based transparent conductive thin film is formed by periodically doping the Group III element to the thin film, the electrical characteristics of the thin film are enhanced.

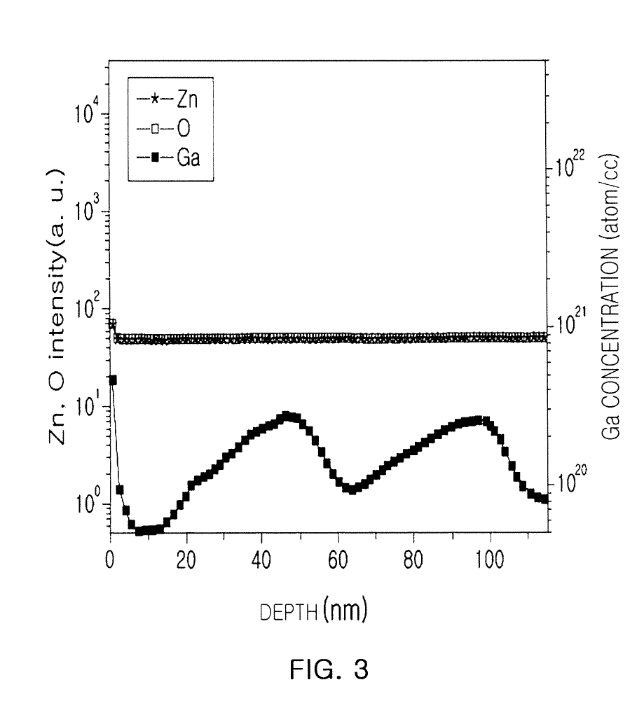

FIG. 3 is an SIMS graph of a concentration of a Group III element over a thickness of a zinc oxide-based transparent conductive thin film formed by using the method of fabricating a zinc oxide-based transparent conductive thin film according to an example of the present application.

As illustrated in FIG. 3, the concentration of Ga is evenly distributed, according to the depth of the transparent conductive thin film. Namely, the Group III element is evenly distributed within the entire transparent conductive thin film, rather than being distributed only to the surface of the transparent conductive thin film.

When the Group III element is evenly distributed over the entirety of the thin film, resistance of the thin film is reduced and conductivity thereof is increased, obtaining a thin film having excellent electrical characteristics.

Namely, when the zinc oxide-based transparent conductive thin film of a semiconductor light emitting device is formed by using the foregoing method, the semiconductor light emitting device may be fabricated to have excellent electrical characteristics.

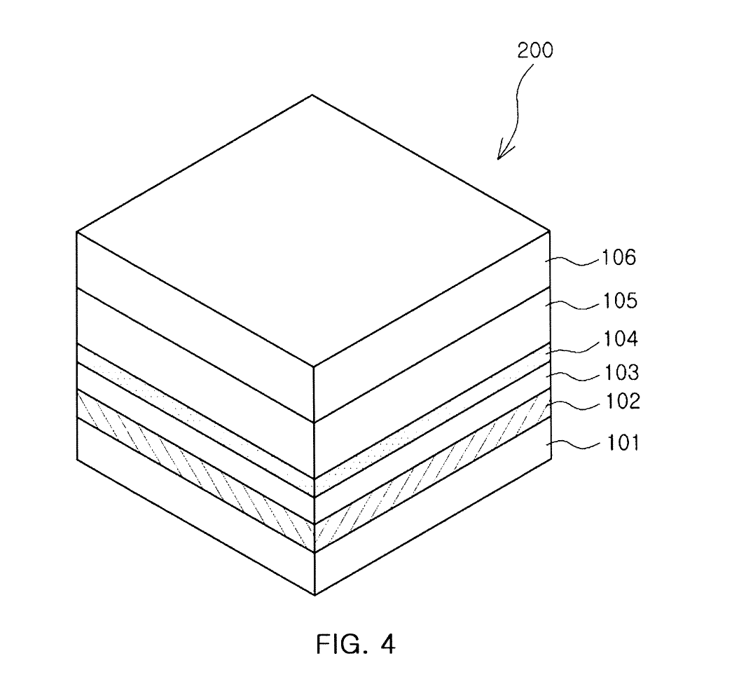

FIG. 4 is a schematic perspective view schematically showing a semiconductor light emitting device including a zinc oxide-based transparent conductive thin film according to an example of the present application.

With reference to FIG. 4, a semiconductor light emitting device 200 including a zinc oxide-based transparent conductive thin film according to an example of the present application is a vertical light emitting device including a p-type semiconductor layer 103, an active layer 104, and an n-type semiconductor layer 105 sequentially stacked on an upper portion of a substrate 101.

As the substrate 101, a substrate made of copper (Cu), silicon (Si), or the like may be used.

The p-type semiconductor layer 103 is a p-type material layer made of a GaN series Group III-V nitride-based compound. Preferably, the p-type semiconductor layer 103 is a direct transition-type semiconductor layer in which a p-type conductive impurity is doped, and more preferably, the p-type semiconductor layer 103 is a p-GaN layer. Besides, the p-type semiconductor layer 103 may be a material layer, e.g., an AlGaN layer or an InGaN layer, in which aluminum (Al) or indium (In) is contained at a certain ratio in the GaN series Group III-V nitride-based compound.

The n-type semiconductor layer 105 is an n-type material layer made of a GaN series III-V nitride-based compound, and preferably, it is an n-GaN layer. Besides, the n-type semiconductor layer 105 may be a material layer, e.g., an AlGaN layer or an InGaN layer, in which aluminum (Al) or indium (In) is contained at a certain ratio in the GaN series Group III-V nitride-based compound.

The active layer 104 is a material layer in which light emission occurs according to the recombination of carriers such as electron-hole recombination, or the like. Preferably, the active layer 104 is a material layer made of a GaN series Group III-V nitride-based compound having a multi-quantum well (MQW) structure. Among these compounds, the active layer 104 is preferably an InxAlyGal-x-yN (0≦x≦1, 0≦y≦1, x+y≦1) layer. Besides, the active layer 104 may be a material layer, e.g., an InGaN layer in which indium (In) is contained at a certain ratio in a GaN series Group III-V nitride-based compound. Meanwhile, the p-type semiconductor layer 103, the active layer 104, and the n-type semiconductor layer 105 are not limited thereto and may be variably configured.

A p-type electrode 102 is electrically in contact with the p-type semiconductor layer 103, and an n-type electrode 106 is electrically in contact with the n-type semiconductor layer 105. Namely, the p-type electrode 102 is disposed between the p-type semiconductor layer 103 and the substrate 101 and is in contact with the p-type semiconductor layer 103, while the n-type electrode 106 is disposed on the n-type semiconductor layer 105 and is in contact with the n-type semiconductor layer 105.

Light generated in the active layer 104 may be sequentially discharged (or emitted) to the outside through the n-type semiconductor layer 105 and the n-type electrode 106. In this case, the n-type electrode 106 is formed as a transparent electrode allowing light to be transmitted therethrough to the outside, and in particular, the n-type electrode 106 may be configured as a zinc oxide-based transparent conductive thin film.

When the transparent electrode is formed as a zinc oxide-based transparent conductive thin film, a semiconductor light emitting device having enhanced electrical characteristics can be fabricated.

Also, when the zinc oxide-based transparent conductive thin film is formed by using the batch-type MOCVD device according to an example of the present application, the zinc oxide-based transparent conductive thin film can be formed on tens of sheets of wafers (W) at a time, allowing for mass-production to reduce unit costs.

As set forth above, according to examples of the application, a zinc oxide-based transparent conductive thin film having enhanced electrical characteristics can be formed.

Also, a zinc oxide-based transparent conductive thin film that has excellent electrical characteristics and is available for mass-production can be formed by using the batch-type MOCVD device.

Thus, a semiconductor light emitting device having enhanced electrical characteristics can be fabricated.

While the foregoing has described what are considered to be the best mode and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

What is claimed is:

1. A semiconductor light emitting device having a zinc oxide-based transparent conductive thin film in which a Group III element is doped to have waveforms having a plurality of periods in a thickness direction.

2. A method of fabricating a semiconductor light emitting device, the method comprising:
forming a light emitting structure in which a first conductivity-type semiconductor layer, an active layer, and a second conductivity-type semiconductor layer are sequentially stacked on a substrate;
performing a heat treatment on the substrate;
injecting a zinc precursor and an oxidizing agent into a reaction chamber to grow a zinc oxide-based thin film;
periodically injecting a Group III element precursor into the reaction chamber to dope the Group III element in the zinc oxide-based thin film, while the zinc oxide-based thin film is being grown; and
performing a heat treatment on the resultant material.

3. The method of claim 2, wherein the heat treatment, before growing the zinc oxide-based thin film, is performed at a temperature ranging from 200° C. to 600° C. for 10 to 60 minutes.

4. The method of claim 2, wherein the zinc precursor includes any one of diethylzinc (DEZn) or dimethylzinc (DMZn).

5. The method of claim 2, wherein the precursor used as the Group III element includes at least one of triethylgallium (TEGa) and trimethylgallium (TMGa).

6. The method of claim 2, wherein the growing of the zinc oxide-based thin film is performed at a temperature ranging from 400° C. to 530° C. under an atmospheric pressure ranging from 2 to 30 torr.

7. The method of claim 2, wherein the heat treatment is performed on the resultant material at a temperature ranging from 200° C. to 600° C. for 40 to 120 minutes.

8. The method of claim 2, wherein the zinc oxide-based transparent conductive thin film is formed in a batch-type metal-organic chemical vapor deposition (MOCVD) device.

9. A method of fabricating a semiconductor light emitting device, the method comprising:
forming a light emitting structure in which a first conductivity-type semiconductor layer, an active layer, and a second conductivity-type semiconductor layer are sequentially stacked on a substrate; and
repeatedly performing a process of injecting a zinc precursor, an oxidizing agent, and a precursor of a Group III element into a reaction chamber to grow a zinc oxide-based thin film from at least one surface of the light emitting structure, and then, injecting the zinc precursor and the oxidizing agent, excluding the Group III element precursor, into the reaction chamber to grow the zinc oxide-based transparent conductive thin film for 2 to 20 minutes.

10. The method of claim 9, wherein the zinc precursor includes diethylzinc (DEZn) or dimethylzinc (DMZn).

11. The method of claim 9, wherein the precursor used as the Group III element includes at least one of triethylgallium (TEGa) and trimethylgallium (TMGa).

12. The method of claim 9, wherein the growing of the zinc oxide-based thin film is performed at a temperature ranging from 400° C. to 530° C. under an atmospheric pressure ranging from 2 to 30 torr.

13. The method of claim 9, wherein the zinc oxide-based transparent conductive thin film is formed in a batch-type metal-organic chemical vapor deposition (MOCVD) device.
